(19) United States
(12) Patent Application Publication
(10) Pub. No.: US 2016/0053116 A1
(43) Pub. Date: Feb. 25, 2016

(54) POLYMER SOLUTION, POLYMER FILM, STACKED COMPOSITE, DISPLAY ELEMENT, OPTICAL ELEMENT, ILLUMINATION ELEMENT, AND PRODUCTION METHOD THEREFOR

(71) Applicant: SUMITOMO BAKELITE CO., LTD., Shinagawa-ku, Tokyo (JP)

(72) Inventors: Toshimasa EGUCHI, Kobe-shi (JP); Hideo UMEDA, Kobe-shi (JP); Ritsuya KAWASAKI, Kobe-shi (JP); Toshihiko KATAYAMA, Nishinomiya-shi (JP); Manabu NAITO, Kobe-shi (JP)

(73) Assignee: SUMITOMO BAKELITE CO., LTD., Shinagawa-ku, Tokyo (JP)

(21) Appl. No.: 14/783,304

(22) PCT Filed: Apr. 2, 2014
(86) PCT No.: PCT/JP2014/059715

§ 371 Date: Oct. 8, 2015

(30) Foreign Application Priority Data
Apr. 8, 2013 (JP) 2013-080646

(51) Int. Cl. C08L 79/04; C03C 17/28; H01L 51/56; C08J 5/18

(52) U.S. Cl. CPC C08L 79/04; C08J 5/18; C03C 17/28; H01L 51/56; C08L 2203/16; C08L 2203/20; C08J 2379/04

(57) ABSTRACT

In one aspect, a polymer film having improved mechanical properties is provided. In one aspect, a polymer solution containing a solvent and a polymer that contains either a structural unit having a benzoxazole precursor structure or a structural unit having a benzoxazole structure is provided.

### TECHNICAL FIELD

The present disclosure relates to a polymer solution, a polymer film formed with the polymer solution, a stacked composite including the polymer film, a display element, an optical element, and an illumination element that include the polymer film, as well as methods for producing these

### BACKGROUND ART

As a display element is required to have transparency, a glass substrate in which a glass plate is used has been used as a substrate for the display element (Patent Document 1: JP10311987(A)). But it has been pointed out in some cases that a display element in which a glass substrate is used has problems such as a heavy weight, being easy to break, and being unbent. To cope with this, an attempt to use a transparent resin film in place of a glass substrate has been proposed.

As a transparent resin for optical use, polycarbonate having high transparency, or the like, has been known, but in the case where polycarbonate is used in the production of a display element, there arise problems relating to heat-resisting properties and mechanical strength thereof. On the other hand, polyimide, for example, is used as a heat-resistant resin, but common polyimide has problems when used for optical use since it is colored in dark brown. Further, polyimide having a cyclic structure has been known as polyimide having transparency, but it has a problem of low heat-resisting properties.

WO 2004/039863 (Patent Document 2) and JP2008260266(A) (Patent Document 3) disclose, as an optical polyamide film, aromatic polyamide having diamine including a trifluoro group, which has both of high rigidity and heat-resisting properties.

### PRIOR ART DOCUMENT

### Patent Document

[Patent Document 1] JP10(1998)-311987A

[Patent Document 2] WO2004/039863

[Patent Document 3] JP2008-260266A

### SUMMARY OF THE INVENTION

### Problem to be Solved by the Invention

The present disclosure, in one aspect, provides a polymer film having improved mechanical properties.

### Means for Solving the Problem

The present disclosure, in one aspect, relates to a polymer solution containing: a solvent; and a polymer that contains either a structural unit having a benzoxazole precursor structure or a structural unit having a benzoxazole structure.

The present disclosure, in one aspect, relates to a polymer film formed with the polymer solution according to the present disclosure. Further, the present disclosure, in another aspect, relates to a stacked composite that includes a glass plate and a polymer film layer, wherein the polymer film is stacked over one of surface of the glass plate, the stacked composite being obtained or being obtainable by applying the polymer solution according to the present disclosure over the glass plate.

The present disclosure, in one aspect, relates to a method for producing a display element, an optical element, or, an illumination element, the method including the step of forming a display element, an optical element, or an illumination element on a surface of the polymer layer of the stacked composite according to the present disclosure, the surface being on a side opposite to a glass-plate-side surface of the polymer layer; and further relates to a display element, an optical element, or, an illumination element that is produced by the aforementioned method.

### Effect of the Invention

The polymer solution according to the present disclosure, in one or more embodiments, enables to form a polymer film having improved mechanical properties.

### BRIEF DESCRIPTION OF DRAWINGS

FIG. 1 is a schematic cross-sectional view illustrating a configuration of an organic electroluminescent (EL) element 1 according to one embodiment.

FIG. 2 is a flowchart for explaining a method for producing an OLED element according to one embodiment.

### EMBODIMENTS FOR CARRYING OUT THE INVENTION

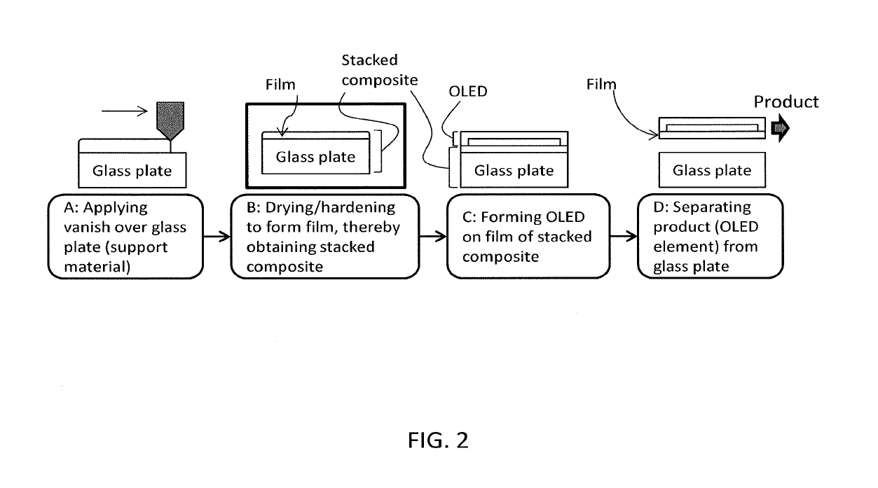

A display element, an optical element, or an illumination element such as an organic electroluminescence (OEL), or an organic light-emitting diode (OLED), for example, is often produced by a method illustrated by the flowchart of FIG. 2. More specifically, first, a polymer solution (vanish) is applied or casted over a glass support material or a silicon wafer (Step A). Next, the polymer solution thus applied or casted is dried or hardened, whereby a film is formed (Step B). On the film, an element such as an OLED or the like, for example, is formed (Step C), and thereafter, as required, the element (product) such the OLED or the like is separated from the support material (Step D).

In a case where a vanish of aromatic polyamide is used as a polymer solution in the production illustrated in FIG. 2 for producing a display element, an optical element, or an illumination element, mechanical properties of the aromatic polyamide film are an issue in some cases. More specifically, the aromatic polyamide film, which has a high Young's modulus but a low elongation percentage, is a fragile material. Therefore, by increasing the elongation percentage of the polyamide film, the handleability of the formed film is improved, and film breakage can be suppression.

The present disclosure is based on knowledge that in a case where an oxazole precursor structure or a benzoxazole structure is present in a polymer of a polymer solution, when a film is formed from the polymer solution, mechanical properties, particularly, tenacity can be imparted to the film. In the present disclosure, the tenacity is expressed quantitatively as fracture energy. The fracture energy is a value obtained by integrating stress (Pa=N/m²) until a sample is broken in a tension test, by a displacement (dimensionless), and the unit thereof is J/m³. More specifically, the fracture energy can be measured by a method described in the description of Example.

The present disclosure, therefore, in one aspect, relates to a polymer solution that includes: a solvent; and a polymer that contains a structural unit having a benzoxazole precursor structure or a structural unit having a benzoxazole structure (hereinafter referred to as a “polymer solution according to the present disclosure” as well).

### [Polymer in Polymer Solution]

In the polymer in the polymer solution according to the present disclosure, in one or more embodiments, a sum of the structural unit having a benzoxazole precursor structure and the structural unit having a benzoxazole structure with respect to the total structural units composing the polymer is in the following range, from the viewpoint of improving the tenacity of the polymer film to be formed: more than 0; 0.1 mol % or more; 1.0 mol % or more; 3.0 mol % or more; 5.0 mol % or more; 6.0 mol % or more; 7.0 mol % or more; 8.0 mol % or more; 9.0 mol % or more; or 10.0 mol % or more.

Further, in the polymer in the polymer solution according to the present disclosure, in one or more embodiments, the sum of the structural unit having a benzoxazole precursor structure and the structural unit having a benzoxazole structure with respect to the total structural units composing the polymer is in the following range, from the viewpoint of improving transparency of the polymer film to be formed: 100 mol % or less; 50 mol % or less; less than 50 mol %; 45 mol % or less; 40 mol % or less; 35 mol % or less; 30 mol % or less; 25 mol % or less; or 20 mol % or less.

Then, in the polymer in the polymer solution according to the present disclosure, in one or more embodiments, the sum of the structural unit having a benzoxazole precursor structure and the structural unit having a benzoxazole structure with respect to the total structural units composing the polymer is in the following range from the viewpoint of improving tenacity of the polymer film to be formed, and from the viewpoint of improving transparency of the polymer film to be formed: more than 0 mol % and equal to or less than 100 mol %; more than 0 mol % and equal to or less than 50 mol %; equal to or more than 0.1 mol % and less than 50 mol %; 1.0 to 45 mol %; 3.0 to 40 mol %; 5.0 to 40 mol %; 5.0 to 35 mol %; 6.0 to 30 mol %; 7.0 to 30 mol %; 8.0 to 25 mol %; 9.0 to 25 mol %; or 10.0 to 20 mol %.

Examples of the polymer in the polymer solution according to the present disclosure, in one or more embodiments, include transparent resins, and those which can form a transparent film. More specifically, examples of the same include: polyolefin (polyethylene, polypropylene, polynorbornene, etc.), amorphous polyolefin, polyimide, polyamide-imide, polyamide, polyether-imide, polyether ether ketone, polyether ketone, polyketone sulfide, polyether sulfone, polysulfone, polyphenylene sulfide, polyphenylene oxide, polyethylene terephthalate, polybutylene terephthalate, polyethylene naphthalate, polyacetal, polycarbonate, polyarylate, polymethyl methacrylate, polymethacrylate, polyacrylate, polystyrene, polypropylene, polynorbornene, cellulosic polymer (triacetyl cellulose (TAC), etc.), and mixtures of these. The polymer in the polymer solution according to the present disclosure, in one or more embodiments, contains a polymer obtained when the above-described polymer having a benzoxazole precursor structure forms a benzoxazole structure.

The polymer in the polymer solution according to the present disclosure, in one or more embodiments, is polyamide. In one or more embodiments, the polymer may contain a polymer obtained when polyamide having a benzoxazole precursor structure forms a benzoxazole structure.

### [Structural Unit Having Benzoxazole Precursor Structure]

In the polymer in the polymer solution according to the present disclosure, examples of the structural unit having a benzoxazole precursor structure, in one or more embodiments, include a structural unit having a group expressed by the chemical formula shown below:

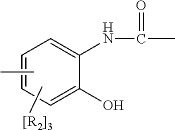

In the foregoing formula, R₂ represents an arbitrary substituent group. The three R₂ groups may be identical or different.

In the polymer in the polymer solution according to the present disclosure, the structural unit having a benzoxazole precursor structure, in one or more embodiments, is at least one selected from the group consisting of structural units expressed as the chemical formulae shown below:

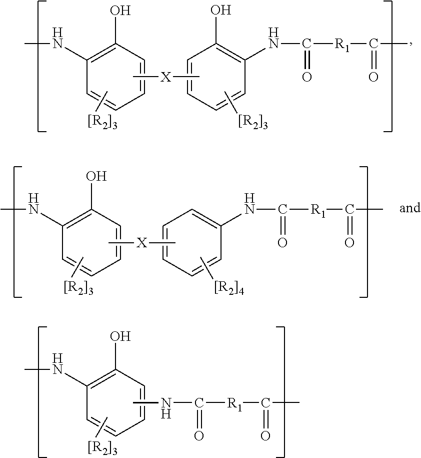

In the above formulae, R₁ represents a group having an aromatic ring or an alicyclic structure, and R₂ represents an arbitrary substituent group. The three or four R₂ groups may be identical or different. X represents a divalent atom or a divalent organic group.

In the structural unit having a benzoxazole precursor structure expressed as the above formulae, R₁ represents a divalent group having an aromatic ring or an alicyclic structure. Examples of the divalent group having an aromatic ring, in one or more embodiments, include groups expressed by the chemical formulae shown below, and groups obtained by substituting these groups with one or more substituent groups.

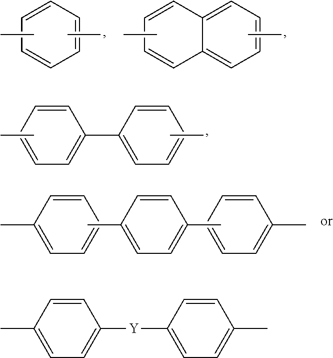

[where examples of Y include a group containing Si, a group containing P, a group containing S, a halogenated hydrocarbon group, and a group containing O, and examples of the same, in one non-limited embodiment, include —S—, —SO₂—, and —(CF₃)₂C—]. Examples of the above-described substituent group, in one or more embodiments, include one or more substituent groups selected from the group consisting of a hydrogen atom, deuterium, halogen, hydrocarbon groups having 1 to 5 carbon atoms, halogen-substituted hydrocarbon groups having 1 to 5 carbon atoms, —CF₃, —CCl₃, —Cl₃, —CBr₃, —I, —NO₂, —CN, —COCH₃, —CO₂C₂H₅, —OH, —COOH, and —OCH₃. Further, examples of the divalent group having an alicyclic structure include the above-described divalent group having an aromatic ring wherein the benzene ring structure is hydrogenated.

In the present disclosure, in one or more embodiments, the phrase of “substituted” or “may be substituted” signifies, for example, being substituted by one or more substituent groups selected from the group consisting of a hydrogen atom, deuterium, halogen, hydrocarbon groups having 1 to 5 carbon atoms, halogen-substituted hydrocarbon groups having 1 to 5 carbon atoms, —CF₃, —CCl₃, —Cl₃, —CBr₃, —I, —NO₂, —CN, —COCH₃, —CO₂C₂H₅, —OH, —COOH, and —OCH₃, unless particularly explained. In the present disclosure, examples of the halogen atom include a fluorine atom (F), a chlorine atom (Cl), and a bromine atom (Br).

In the structural unit having a benzoxazole precursor structure expressed by the above-described formulae, R₂ represents an arbitrary substituent group, and in one or more embodiments, examples of the same include a hydrogen atom, deuterium, halogen, hydrocarbon groups having 1 to 5 carbon atoms, halogen-substituted hydrocarbon groups having 1 to 5 carbon atoms, —CF₃, —CCl₃, —Cl₃, —CBr₃, —I, —NO₂, —CN, —COCH₃, —CO₂C₂H₅, —OH, —COOH, and —OCH₃.

In the structural unit having a benzoxazole precursor structure expressed by the above-described formulae, X represents a divalent atom or a divalent organic group. Examples of the divalent atom, in one or more embodiments, include an oxygen atom, and a sulfur atom. Examples of the divalent organic group, in one or more embodiments, include an alkylene group, a halogenated hydrocarbon group, a group having an ether bond, and a divalent cyclic-structure-containing organic group. Examples of the alkylene group, in one or more embodiments, include an alkylene group having 1 to 6 carbon atoms, —CH₂—, —C(CH₃)₂—, —(CH₂)₃—, and —(CH₂)₅. Examples of the halogenated hydrocarbon group, and a group having an ether bond, in one or more embodiments, include —O—, —S—, —C(CF₃)₂—, —C(CCl₃)₂—, —C(CBr₃)₂—, —CF₂—, —CCl₂—, and —CBr₂—. Examples of the divalent cyclic-structure-containing organic group include

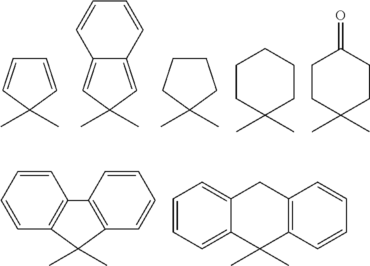

and these groups substituted by one or more substituent groups.

### [Structural Unit Having Benzoxazole Structure]

In the polymer in the polymer solution according to the present disclosure, examples of the structural unit having a benzoxazole structure, in one or more embodiments, include structural units having a group expressed by the chemical formula shown below:

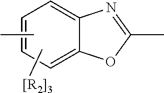

In the above-described formula, R₂ represents an arbitrary substituent group. The three R₂ groups may be identical or different. Examples of R₂ include those in the above-described one or more embodiments.

In the polymer in the polymer solution according to the present disclosure, the structural unit having a benzoxazole structure, in one or more embodiments, is a constituent unit in which polyamide having a benzoxazole precursor structure forms a benzoxazole structure, and is, for example, at least one selected from the group consisting of structural units expressed by the chemical formulae shown below:

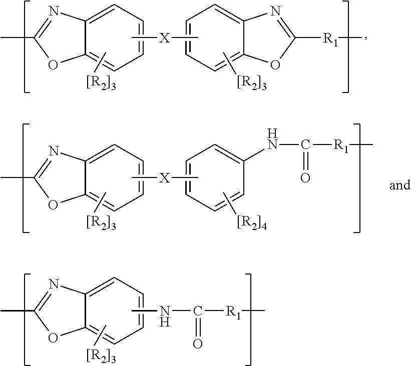

In the above-described formulae, R₁ represents a group having an aromatic ring or an alicyclic structure, R₂ represents an arbitrary substituent group. The three or four R₂ groups may be identical or different. X represents a divalent atom or a divalent organic group. Examples of R₁, R₂, and X include those in the above-described one or more embodiments.

The polymer solution according to the present disclosure, therefore, in one or more embodiments, is a polymer solution that contains a plurality of units of at least one type selected from the group consisting of the structural units expressed by chemical formulae shown below:

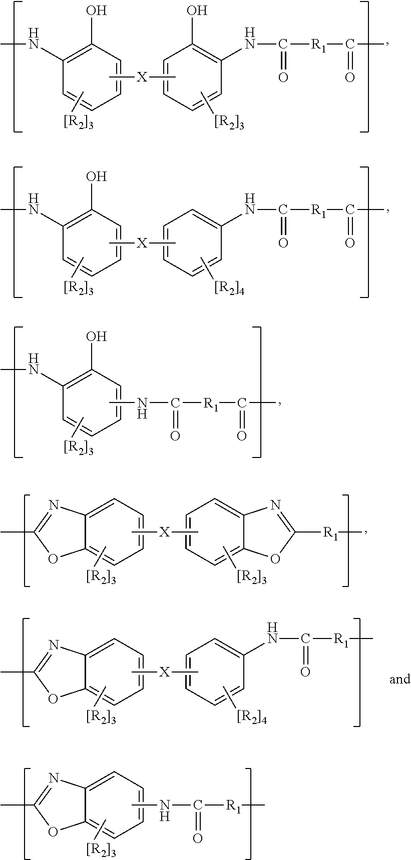

where the X atoms/groups are identical or different, and so are the R₁ groups. Examples of R₁, R₂ and X include those in the above-described one or more embodiments.

The polymer in the polymer solution according to the present disclosure, in one or more embodiments, is obtained or is obtainable by polymerization reaction between a dicarboxylic acid dichloride component monomer and a diamine component monomer. In the case where the polymer in the polymer solution according to the present disclosure is obtained or is obtainable by polymerization reaction between a dicarboxylic acid dichloride component monomer and a diamine component monomer, in one or more embodiments, the amount of the diamine component monomer having a benzoxazole precursor structure with respect to the total amount of the diamine component monomers used in the synthesis of the polyamide is more than 0, 0.1 mol % or more, 1.0 mol % or more, 3.0 mol % or more, 5.0 mol % or more, 6.0 mol % or more, 7.0 mol % or more, 8.0 mol % or more, 9.0 mol % or more, or 10.0 mol % or more, from the viewpoint of improving the tenacity of the polymer film to be formed.

Further, in the case where the polymer in the polymer solution according to the present disclosure is obtained or is obtainable by polymerization reaction between a dicarboxylic acid dichloride component monomer and a diamine component monomer, in one or more embodiments, the amount of the diamine component monomer having a benzoxazole precursor structure with respect to the total amount of the diamine component monomers used in the synthesis of the polyamide is 100 mol % or less, 50 mol % or less, less than 50 mol %, 45 mol % or less, 40 mol % or less, 35 mol % or less, 30 mol % or less, 25 mol % or less, or 20 mol % or less.

Still further, in the case where the polymer in the polymer solution according to the present disclosure is obtained or is obtainable by polymerization reaction between a dicarboxylic acid dichloride component monomer and a diamine component monomer, in one or more embodiments, the amount of the diamine component monomer having a benzoxazole precursor structure with respect to the total amount of the diamine component monomers used for the synthesis of the polyamide is more than 0 mol % and equal to or less than 100 mol %, more than 0 mol % and equal to or less than 50 mol %, equal to or more than 0.1 mol % and less than 50 mol %, 1.0 to 45 mol %, 3.0 to 40 mol %, 5.0 to 40 mol %, 5.0 to 35 mol %, 6.0 to 30 mol %, 7.0 to 30 mol %, 8.0 to 25 mol %, 9.0 to 25 mol %, or 10.0 to 20 mol %, from the viewpoint of improving of the tenacity of the polymer film to be formed and the viewpoint of improving of the transparency of the polymer film to be formed.

### [Diamine Component Monomer Having Benzoxazole Precursor Structure]

Examples of the diamine component monomer having a benzoxazole precursor structure, in one or more embodiments, include:

compounds having dihydroxy-benzene, such as 2,4-diamino-resorcinol, and 2,5-diamino-1,4-dihydroxy-benzene;

bisaminophenol compounds having dihydroxy-biphenyl, such as 3,3′-diamino-4,4′-dihydroxy-biphenyl, and 3,3′-dihydroxy-4,4′-diamino-biphenyl;

bisaminophenol compounds having dihydroxy-diphenyl ether, such as 3,3′-diamino-4,4′-dihydroxy-diphenyl ether;

compounds having a fluorene skeleton, such as 9,9-bis(3-amino-4-hydroxy-phenyl)fluorene, and 9,9-bis(4-(4-amino-3-hydroxy)-phenoxy-phenyl)fluorene;

compounds having a binaphthalene skeleton, such as 2,2′-bis-(4-amino-3-hydroxy-phenoxy)-1,1′-binaphthalene;

compounds having a sulphone group, such as 3,3′-diamino-4,4′-dihydroxy-diphenylsulphone, bis(4-(4-amino-3-hydroxy)-phenoxy-phenyl)sulphone, and bis(4-(4-hydroxy-3-amino)phenoxy-phenyl)sulphone; and

compounds having fluorine or a fluorinated alkyl group, such as 2,2-bis(3-amino-4-hydroxyphenyl)hexafluoropropane.

These may be used alone or in combination of two or more, as the diamine component monomer having a benzoxazole precursor structure.

Further, the diamine component monomer having a benzoxazole precursor structure, in one or more embodiments, is, for example, at least one selected from the group consisting of the monomers expressed by the chemical formulae shown below:

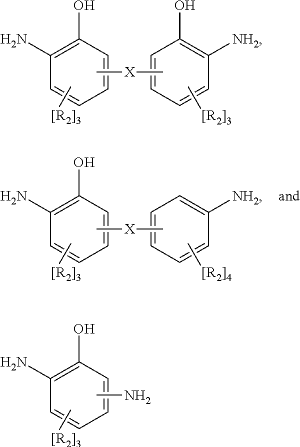

In the formulae shown above, R₂ represents an arbitrary substituent group. The three or four R₂ groups may be identical or different. X represents a divalent atom or a divalent organic group. Examples of R₂ and X include those in the above-described one or more embodiments.

### [Other Constituent Unit]

Structural units other than the structural units having a benzoxazole precursor structure and the structural units having a benzoxazole structure in the polymer in the polymer solution according to the present disclosure are not limited particularly, and examples of the same, in one or more embodiments, include those disclosed in WO2004/039863.

The polymer solution according to the present disclosure, therefore, in one or more embodiments, is a polymer solution that contains a polymer that contains: a structural unit expressed by Chemical Formula (I), (II), or (III), or alternatively, a structural unit expressed by Chemical Formula (IV), (V), or (VI); and a structural unit expressed by Chemical Formula (VII), (VIII), (IX), or (X), wherein expressions (1) to (2) below are satisfied, where mole fractions (mol %) of the structural units expressed by Chemical Formulae (I) to (X) in the polyamide are given as “I”, “m”, “n”, “o”, “p”, “q”, “r”, “s”, “t”, and “u”, respectively:

0<l+m+n+o+p+q≦50 (1)

50≦r+s+t+u<100 (2)

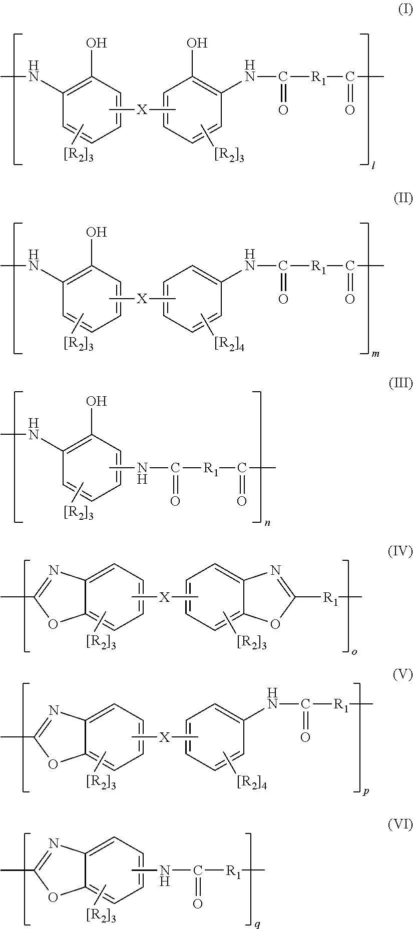

[in Formulae (I) to (VI), R₁ represents a group having an aromatic ring or an alicyclic structure, and R₂ represents an arbitrary substituent group. The three or four R₂ groups may be identical or different. X represents a divalent atom or a divalent organic group.]

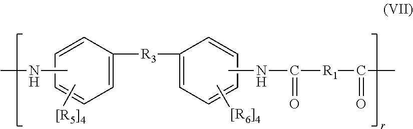

[In Formula (VII), R₃ represents a group having an aromatic ring or an alicyclic structure, R₄ represents a group having an aromatic ring or an alicyclic structure, R₅ represents an arbitrary substituent group, and R₆ represents an arbitrary substituent group. The four R₅ groups may be identical or different, and so are the four R₆ groups. The structural units expressed by Formula (VII), however, do not include the structural units expressed by Formulae (I) and (II).]

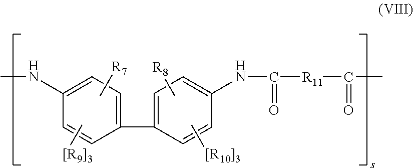

[In Formula (VIII), R₇ represents an electron-withdrawing group, R₈ represents an electron-withdrawing group, R₉ represents an arbitrary substituent group, R₁₀ represents an arbitrary substituent group, and R₁₁ represents a group having an aromatic ring or an alicyclic structure. The three R₉ groups may be identical or different, and so are the three R₁₀ groups. The structural units expressed by Formula (VIII), however, do not include the structural units expressed by Formulae (I) and (II).]

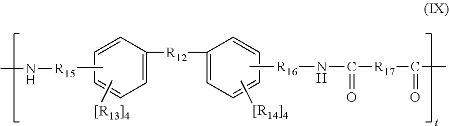

[In Formula (IX), R₁₂ represents a group containing Si, a group containing P, a group containing S, a halogenated hydrocarbon group, or a group containing an ether bond (in the molecule, the structural units having these groups may exist together). R₁₃ represents an arbitrary substituent group, and R₁₄ represents an arbitrary substituent group. R₁₅ represents a directly bonded phenyl group or an arbitrary group having 6 to 12 carbon atoms, the group being containing a phenyl group as an essential component, R₁₆ represents a directly bonded phenyl group or an arbitrary group having 6 to 12 carbon atoms, the group being containing a phenyl group as an essential component, and R₁₇ represents a group having an aromatic ring or an alicyclic structure. The four R₁₃ groups may be identical or different, and so are the four R₁₄ groups. The structural units expressed by Formula (IX), however, do not include the structural units expressed by Formulae (I) and (II).]

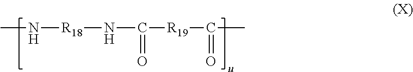

[In Formula (X), R₁₈ represents a group having an aromatic ring or an alicyclic structure, and R₁₉ represents a group having an aromatic ring or an alicyclic structure. The structural units expressed by Formula (X), however, do not include the structural units expressed by Formula (III).]

In expression (1), at least one structural unit expressed by any of Formulae (I) to (VI) may exist, and l, m, n, o, p, and q, which represent the mole fractions (mol %) of the same, respectively, may be 0 as long as expression (1) is satisfied. The value of l+m+n+o+p+q, in one or more embodiments, is more than 0 and equal to or less than 100, 0.1 or more and 50 or less, 1.0 to 45, 3.0 to 40, 5.0 to 40, 5.0 to 35, 6.0 to 30, 7.0 to 30, 8.0 to 25, 9.0 to 25, or 10.0 to 20.

In expression (2), at least one structural unit expressed by any of Formula (VII) to (X) may exist, and r, s, t, and u, which represent the mole fractions (mol %) of the same, may be 0 as long as expression (2) is satisfied. The value of l+m+n+o+p+q+r+s+t+u, in one or more embodiments, more than 50 and equal to or less than 100, 60 to 100, 70 to 100, 80 to 100, or 90 to 100, for example.

Examples of R₁, R₂ and X in Formulae (I) to (VI) include those in the above-described one or more embodiments.

In Formula (VII) described above, R₃ is a group having an aromatic ring or an alicyclic structure, and in one or more embodiments, is a group having a hetero ring. Examples of the shape of the ring is, in one or more embodiments, include a single ring, a condensed ring, and a spiro ring. Examples of R₃, which is a group having an aromatic ring or an alicyclic structure, in one or more embodiments, include those expressed by the formulae shown below:

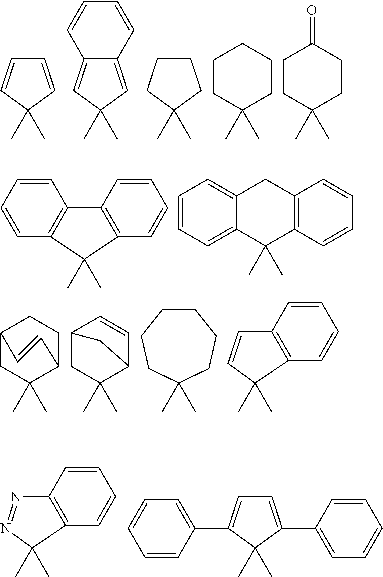

R₄ represents a group having an aromatic ring or an alicyclic structure, and examples of the same include the above-described examples of R₁ in Formulae (I) to (VI) in the above-described one or more embodiments. Further, R₅ and R₆ are not limited particularly, and represent arbitrary groups; examples of the same, in one or more embodiments, include —H, an aliphatic group having 1 to 5 carbon atoms, —CF₃, —CCl₃, —OH, —COOH, —F, —CI, —Br, —OCH₃, a silyl group, and an aromatic group. The structural units expressed by Formula (VII) described above do not include the structural units having a benzoxazole precursor structure and the structural units having a benzoxazole structure. In one or more embodiments, therefore, the structural units expressed by Formula (VII) described above do not include the structural units expressed by Formulae (I) to (VI), or do not include the structural units expressed by Formulae (I) and (II).

In Formula (VIII), R₇ and R₈ are independent electron-withdrawing groups, and may be identical or different. The electron-withdrawing group is, in one or more embodiments, a group that exhibits a positive value as a Hammett substituent constant, and examples of the same include —CF₃, —CCl₃, —Cl₃, —CBr₃, —F, —Cl, —Br, —I, —NO₂, —CN, —COCH₃, and —CO₂C₂H₅. Further, R₉ and R₁₀ are not limited particularly, and represent arbitrary groups. Examples of the same, in one or more embodiments, include —H, an aliphatic group having 1 to 5 carbon atoms, —CF₃, —CCl₃, —OH, —COOH, —F, —CI, —Br, —OCH₃, a silyl group, and an aromatic group. R₁₁ is a group having an aromatic ring or an alicyclic structure, and examples of the same include the above-described examples of R₁ in Formulae (I) to (VI) in the above-described one or more embodiments. The structural units expressed by Formula (VIII) do not the structural units having a benzoxazole precursor structure and the structural units having a benzoxazole structure. In one or more embodiments, therefore, the structural units expressed by Formula (VIII) do not include the structural units expressed by Formula (I) to (VI), or do not include the structural units expressed by Formula (I) and (II).

In Formula (IX), Rig represents a group containing Si, a group containing P, a group containing S, a halogenated hydrocarbon group, or a group containing an ether bond (in the molecule, the structural units having these groups may exist together). R₁₂ is, in one or more embodiments, —SO₂—, —O—, —C(CF₃)₂—, —(CCl₃)₂—, —(CBr₃)₂—, —CF₂—, —CCl₂—, or —CBr₂. R₁₃ and R₁₄ are not limited particularly, and are independent arbitrary groups, respectively. Examples of R₁₃ and R₁₄, in one or more embodiments, include —H, an aliphatic group having 1 to 5 carbon atoms, —CF₃, —CCl₃, —OH, —COOH, —F, —Cl, —Br, —OCH₃, a silyl group, and an aromatic group. Each of R₁₅ and R₁₆ represents a directly bonded phenyl group or an arbitrary group having 6 to 12 carbon atoms, the group being containing a phenyl group as an essential component, and examples of the same, in one or more embodiments, include -Ph-, —O-Ph-, and —C(CF₃)₂-Ph-. R₁₇ is a group having an aromatic ring or an alicyclic structure, and examples of the same include the above-described examples of R₁ in Formulae (I) to (VI) in the above-described one or more embodiments. The structural units expressed by Formula (IX) do not include the structural units having a benzoxazole precursor structure and the structural units having a benzoxazole structure. In one or more embodiments, therefore, the structural units expressed by Formula (IX) do not include the structural units expressed by Formulae (I) to (VI), or do not include the structural units expressed by Formulae (I) and (II).

In Formula (X) described above, R₁₈ and R₁₉ are independent groups having an aromatic ring or an alicyclic structure, and examples of the same include the above-described examples of R₁ in Formulae (I) to (VI) in the above-described one or more embodiments. Structural units expressed by Formula (X) do not include the structural units having a benzoxazole precursor structure and the structural units having a benzoxazole structure. In one or more embodiments, therefore, the structural units expressed by Formula (X) do not include the structural units expressed by Formulae (I) to (VI) described above, or do not include the structural units expressed by Formula (III) described above.

### [Solvent]

The solvent for the polymer solution according to the present disclosure is not limited particularly. The solvent, in one or more embodiments, may be a solvent used in the preparation of the polymer to be described below. In a case where the polymer is polyamide, examples of the solvent, in one or more embodiments, include aprotic polar solvents. Examples of the same include: sulfoxide-based solvents such as dimethyl sulfoxide and diethyl sulfoxide; formamide-based solvents such as N,N-dimethyl formamide, and N,N-diethyl formamide; acetamide-based solvents such as N,N-dimethylacetamide, and N,N-diethylacetamide; pyrrolidone-based solvents such as N-methyl-2-pyrrolidone, and N-vinyl-2-pyrrolidone; phenol-based solvents such as phenol, o-, m-, or p-cresol, xylenol, halogenated phenol, and catechol; ether-based solvents such as butyl cellosolve, methyl cellosolve, and ethyl cellosolve; glycol-based solvents such as ethylene glycol, and diethylene glycol; glycol ester-based solvents such as ethylene glycol monobutyl ether, polypropylene glycol monobutyl ether, and diethylene glycol monobutyl ether; hexamethyl phosphoramide; γ-butyrolactone; 3-methoxy-N,N-dimethylpropionamide; 3-butoxy-N,N-dimethyl propane amide; N-ethyl pyrrolidone; N,N-dimethylpropionamide; N,N-dimethylbutanamide; N,N-diethylacetamide; N,N-diethylpropionamide; 1-methyl-2-piperidinone; propylene carbonate; and mixtures of these. Further, an aromatic hydrocarbon such as xylene, or toluene, can be used. Still further, a salt of an alkali metal, or an alkali earth metal of 50% by weight or less can be added to the solvent in order to promote the dissolution of the polymer.

### [Filler]

To the polymer solution according to the present disclosure, a filler may be added in order to improve a modulus of elasticity of the polymer film to be formed from the polymer solution. Examples of the filler, in one or more embodiments, include spherical type fillers, fibrous type fillers, flat plate type fillers, and combinations of these.

The polymer in the polymer solution according to the present disclosure, in one or more embodiments, is configured so that at least one end of the polymer is end-capped, from the viewpoint of heat-resistant properties of the polymer. In a case where the polymer is polyamide, —COOH group at a terminal, and one end or both ends of the —NH₂ group, are capped. The end-capping of the polyamide, in one or more embodiments, is achieved by reaction between a —NH₂ terminal of polymerized polyamide and benzoyl chloride, or reaction between a —COOH terminal of polymerized polyamide and aniline. The method of end-capping, however, is not limited to this method.

The film formed with the polymer solution according to the present disclosure, at an equivalent thickness of 10 μm, in one or more embodiments, has a light transmittance at a wavelength of 400 nm of, for example, 60% or more, 65% or more, 70% or more, 75% or more, or 80% or more, from the viewpoint that the film is used suitably in the production of a display element, an optical element, or an illumination element in one or more embodiments. The light transmittance can be measured by a method used in Example.

The film formed with the polymer solution according to the present disclosure, in one or more embodiments, has a fracture energy of, for example, 2.0 MJ/m³ or more, 2.5 MJ/m³ or more, 3.0 MJ/m³ or more, 3.5 MJ/m³ or more, 4.0 MJ/m³ or more, 4.5 MJ/m³ or more, 5.0 MJ/m³ or more, 5.5 MJ/m³ or more, 6.0 MJ/m³ or more, 6.5 MJ/m³ or more, 7.0 MJ/m³ or more, 7.5 MJ/m³ or more, 8.0 MJ/m³ or more, 8.5 MJ/m³ or more, or 9.0 MJ/m³ or more, from the viewpoint of improving the handleability of the film in the production of a display element, an optical element, or an illumination element.

As a film used in the measurement of a light transmittance and a fracture energy, a film produced by casting the polymer solution according to the present disclosure on a glass plate is used. This film is a film obtained by applying the polymer solution according to the present disclosure over a flat glass substrate, drying the same, and hardening the same as required. More specifically, the film is a film formed by a film forming method used in Example disclosed herein.

### [Method for Preparing Polymer]

As a method for obtaining the polymer in the polymer solution according to the present disclosure, various types of methods can be used, the low-temperature solution polymerization method, the interfacial polymerization method, the melt polymerization method, the solid-phase polymerization method, or the like, can be used in one or more non-limited embodiments. Further, the method may be a polymerization method in which a solvent is not used, for example, the vapor deposition polymerization method. In one or more embodiments, in a case where polyamide is obtained by the low-temperature solution polymerization method, in other words, in a case where polyamide is obtained from dicarboxylic acid dichloride and diamine, synthesis is performed in an aprotic polar organic solvent. The following description describes a method for preparing the polymer solution according to the present disclosure.

As dicarboxylic acid dichloride, monomers suitable for the above-described structural unit can be selected appropriately. In one or more non-limited embodiments, examples of the carboxylic acid dichloride include terephthalic acid dichloride, 2-chloro-terephthalic acid dichloride, isophthalic acid dichloride, naphthalene dicarbonyl chloride, biphenyl dicarbonyl chloride, 4,4′-biphenyl dicarbonyl chloride, terphenyl dicarbonyl chloride, 2-fluoro-terephthalic acid dichloride, 1,4-cyclohexane carboxylic acid dichloride, 2,2′-bis(4-carboxyphenyl)propane dichloride, and 2,2′-bis(4-carboxyphenyl)hexafluoropropane dichloride, among which terephthalic acid dichloride, 2-chloro-terephthalic acid dichloride, 4,4′-biphenyl dicarbonyl chloride, or isophthalic acid dichloride is used preferably.

As diamine, a monomer suitable for the above-described structural unit can be selected appropriately. A diamine component monomer having a benzoxazole precursor structure is as described above. Examples of the diamine component monomer, other than the diamine component having a benzoxazole precursor structure, in one or more non-limited embodiments, include bis[4-(4-amino-phenoxy)phenyl]sulphone, bis[4-(3-amino-phenoxy)phenyl]sulphone, 2,2′-ditrifluoromethyl-4,4′-diamino-biphenyl, 9,9-bis(4-amino-phenyl)fluorene, 9,9-bis(4-amino-3-methyl-phenyl)fluorene, 9,9-bis(4-amino-3-fluoro-phenyl)fluorene, 9,9-bis(4-amino-3-chloro-phenyl)fluorene, 2,2-bis[4-(4-amino-phenoxy)phenyl]propane, and 2,2-bis(4-amino-phenyl)hexafluoropropane.

In a case where two or more types of diamines are used for performing polymerization, the following methods can be used: a stepwise reaction method in which the diamines are added one by one, wherein 10 to 99 mol % of diacid chloride with respect to one type of diamine is added so that reaction occurs, and thereafter, another type of diamine is added, and diacid chloride is added further so that reaction occurs; and a method in which diamines of all types are mixed together and added, and thereafter diacid chloride is added so that reaction occurs. Further, in a case where two or more types of diacidic chlorides are used, similarly, the stepwise method, the method of adding materials simultaneously, or the like can be used. In any case, the molar ratio between all diamines and all diacid chlorides is 95 to 105:105 to 95 preferably.

Examples of the aprotic polar solvent used in the production of polyamide include: sulfoxide-based solvents such as dimethyl sulfoxide, and diethyl sulfoxide; formamide-based solvents such as N,N-dimethyl formamide, and N,N-diethyl formamide; acetamide-based solvents such as N,N-dimethylacetamide, and N,N-diethylacetamide; pyrrolidone-based solvents such as N-methyl-2-pyrrolidone, and N-vinyl-2-pyrrolidone; phenol-based solvents such as phenol, o-, m-, or p-cresol, xylenol, halogenated phenol, and catechol; ether-based solvents such as butyl cellosolve, methyl cellosolve, and ethyl cellosolve; glycol-based solvents such as ethylene glycol, and diethylene glycol; glycol ester-based solvents such as ethylene glycol monobutyl ether, polypropylene glycol monobutyl ether, and diethylene glycol monobutyl ether; hexamethyl phosphoramide; γ-butyrolactone; 3-methoxy-N,N-dimethylpropionamide; 3-butoxy-N,N-dimethylpropaneamide; N-ethyl pyrrolidone; N,N-dimethylpropionamide; N,N-dimethylbutanamide; N,N-diethylacetamide; N,N-diethylpropionamide; 1-methyl-2-piperidinone; and propylene carbonate. These may be used alone or as a mixture desirably. Additionally, an aromatic hydrocarbon such as xylene or toluene can be used. Still additionally, in order to promote the dissolution of the polymer, 50% by weight or less of a salt of an alkali metal, or an alkali earth metal, can be added to the solvent.

From the polyamide solution, in a case where diacid chloride and diamine are used as the monomers, hydrogen chloride is by-produced, and to neutralize this, the following is used: an inorganic neutralizer such as calcium hydroxide, calcium carbonate, or lithium carbonate; or an organic neutralizer such as ethylene oxide, propylene oxide, ammonium, triethylamine, triethanolamine, or diethanolamine.

### [Average Molecular Weight of Polymer]

The polymer in the polymer solution according to the present disclosure, in one or more embodiments, preferably has a weight-average molecular weight (Mn) of 6.0×10⁴ or more, 6.5×10⁴ or more, 7.0×10⁴ or more, 7.5×10⁴ or more, or 8.0×10⁴ or more, from the viewpoint of using the film in a display element, an optical element, or an illumination element. Further, from the same viewpoint, in one or more embodiments, the weight-average molecular weight is 5.0×10⁶ or less, 3.0×10⁶ or less, or 1.0×10⁶ or less. Further, a preferable molecular weight distribution (weight-average molecular weight (Mw)/number average molecular weight (Mn)) is 5.0 or less, 4.0 or less, or, 3.0 or less.

### [Content of Polymer]

The content of aromatic polyamide in the polymer solution according to the present disclosure, in one or more embodiments, is 2% by weight or more, 3% by weight or more, or, 5% by weight or more, for example, from the viewpoint of using the film in a display element, an optical element, or an illumination element. From the same viewpoint, the content of aromatic polyamide is 30% by weight or less, or, 20% by weight or less, for example.

### [Use of Polymer Solution]

The polymer solution according to the present disclosure, in one or more embodiments, is a polymer solution to be used in a method for producing a display element, an optical element, or an illumination element, including the following steps a) to c):

a) applying the polymer solution over a support material;

b) after Step a), forming a polymer film on the support; and

c) forming a display element, an optical element, or an illumination element on the polymer film.

Here, the surface of the support material is a glass or silicon wafer.

The present disclosure further relates to one or more embodiments described below.

<A1> A polymer solution containing: a solvent; and a polymer that contains either a structural unit having a benzoxazole precursor structure or a structural unit having a benzoxazole structure.
<A2> The polymer solution according to <A1>, wherein a sum of the structural unit having a benzoxazole precursor structure and the structural unit having a benzoxazole structure with respect to all of the structural units composing the polymer is more than 0 mol % and equal to or less than 50 mol %.
<A3> The polymer solution according to <A1> or <A2>, wherein the structural unit having a benzoxazole precursor structure or the structural unit having a benzoxazole structure is at least one selected from the group consisting of structural units expressed by chemical formulae shown below:

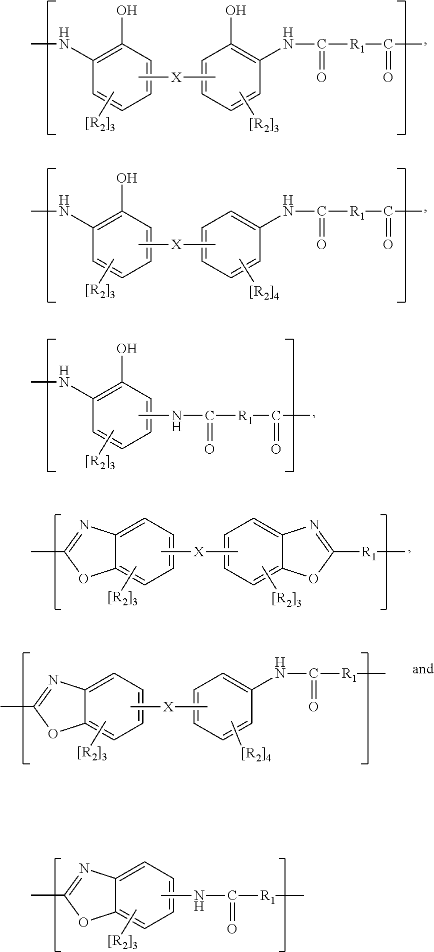

[R₁ represents a group having an aromatic ring or an alicyclic structure, and R₂ represents an arbitrary substituent group. The three or four R₂ groups may be identical or different. X represents a divalent atom or a divalent organic group.]
<A4> The polymer solution according to any one of <A1> to <A3>, wherein an amount of a diamine component monomer having a benzoxazole precursor structure with respect to a total amount of diamine component monomers used in the synthesis of the polymer is more than 0 mol % and equal to or less than 50 mol %.
<A5> The polymer solution according to any one of <A1> to <A4>, wherein the diamine component monomer having a benzoxazole precursor structure used in the synthesis of the polymer is at least one selected from the group consisting of monomers expressed by chemical formulae shown below:

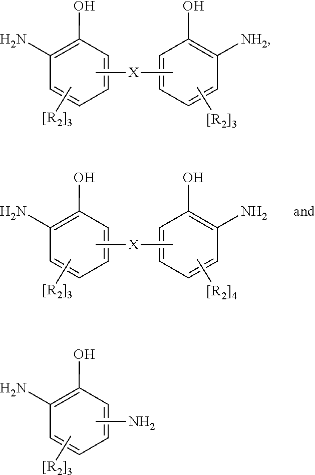

[R₂ represents an arbitrary substituent group. The three or four R₂ groups may be identical or different. X represents a divalent atom or a divalent organic group.]
<A6> The polymer solution according to any one of <A1> to <A5>, wherein a film formed with the polymer solution, at an equivalent thickness of 10 μm, can have a light transmittance at a wavelength of 400 nm of 60% or more.
<A7> The polymer solution according to any one of <A1> to <A6>, wherein the film formed with the polymer solution can have a fracture energy of 2.0 MJ/m³ or more.
<A8> The polymer solution according to any one of <A1> to <A7>, containing a polymer, the polymer containing: a structural unit expressed by Chemical Formula (I), (II) or (III), or alternatively, a structural unit expressed by Chemical Formula (IV), (V) or (VI); and a structural unit expressed by Chemical Formula (VII), (VIII), (IX), or (X), wherein expressions (1) to (2) below are satisfied, where mole fractions of the structural units expressed by Chemical Formulae (I) to (X) in the polyamide are given as “l”, “m”, “n”, “o”, “p”, “q”, “r”, “s”, “t”, and “u”, respectively:

0<l+m+n+o+p+q≦50 (1)

50≦r+s+t+u<100 (2)

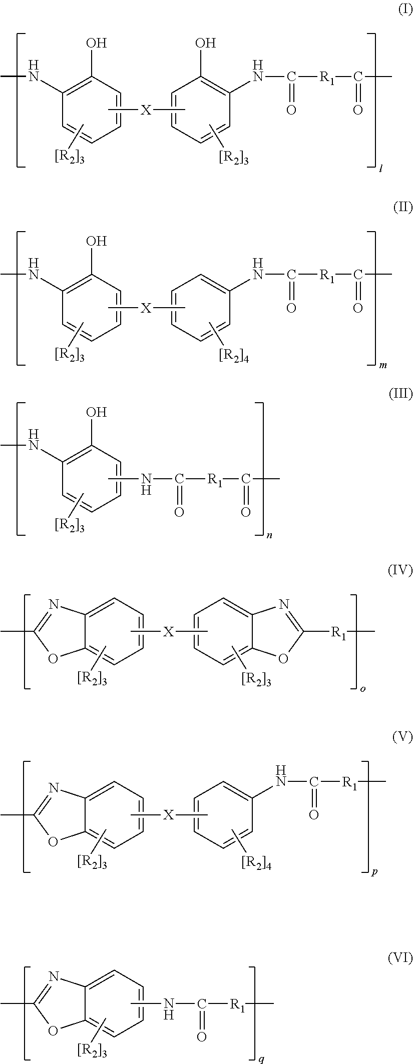

[In Formula (I) to (VI), R₁ represents a group having an aromatic ring or an alicyclic structure, and R₂ represents an arbitrary substituent group. The three or four R₂ groups may be identical or different. X represents a divalent atom or a divalent organic group.]

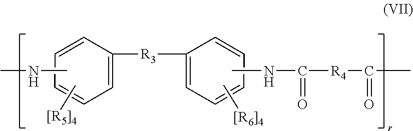

[In Formula (VII), R₃ represents a group having an aromatic ring or an alicyclic structure, R₄ represents a group having an aromatic ring or an alicyclic structure, R₅ represents an arbitrary substituent group, and R₆ represents an arbitrary substituent group. The four R₅ groups may be identical or different, and so are the four R₆ groups. The structural units expressed by Formula (VII), however, do not include the structural units expressed by Formulae (I) and (II).]

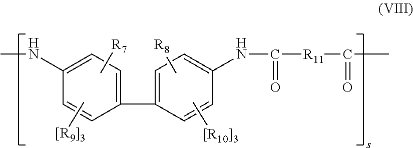

[In Formula (VIII), R₇ represents an electron-withdrawing group, R₈ represents an electron-withdrawing group, R₉ represents an arbitrary substituent group, R₁₀ represents an arbitrary substituent group, and R₁₁ represents a group having an aromatic ring or an alicyclic structure. The three R₉ groups may be identical or different, and so are the three R₁₀ groups. The structural units expressed by Formula (VIII), however, do not include the structural units expressed by Formulae (I) and (II).]

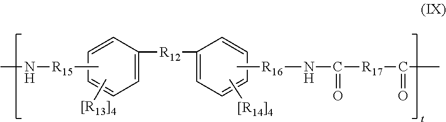

[In Formula (IX), R₁₂ represents a group containing Si, a group containing P, a group containing S, a halogenated hydrocarbon group, or a group containing an ether bond (in the molecule, the structural units having these groups may exist together). R₁₃ represents an arbitrary substituent group, and R₁₄ represents an arbitrary substituent group. R₁₅ represents a directly bonded phenyl group or an arbitrary group having 6 to 12 carbon atoms, the group being containing a phenyl group as an essential component, R₁₆ represents a directly bonded phenyl group or an arbitrary group having 6 to 12 carbon atoms, the group being containing a phenyl group as an essential component, and R₁₇ represents a group having an aromatic ring or an alicyclic structure. The four R₁₃ groups may be identical or different, and so are the four R₁₄ groups. The structural units expressed by Formula (IX), however, do not include the structural units expressed by Formulae (I) and (II).]

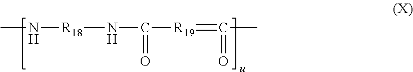

[In Formula (X), R₁₈ represents a group having an aromatic ring or an alicyclic structure, and R₁₉ represents a group having an aromatic ring or an alicyclic structure. The structural units expressed by Formula (X), however, do not include the structural units expressed by Formula (III).]
<A9> The polymer solution according to any one of <A1> to <A8>, wherein at least one end of the polymer is end-capped.
<A10> The polymer solution according to any one of <A1> to <A10>, wherein the polymer contains a plurality of units of at least one type selected from the group consisting of the structural units expressed by chemical formulae shown below.

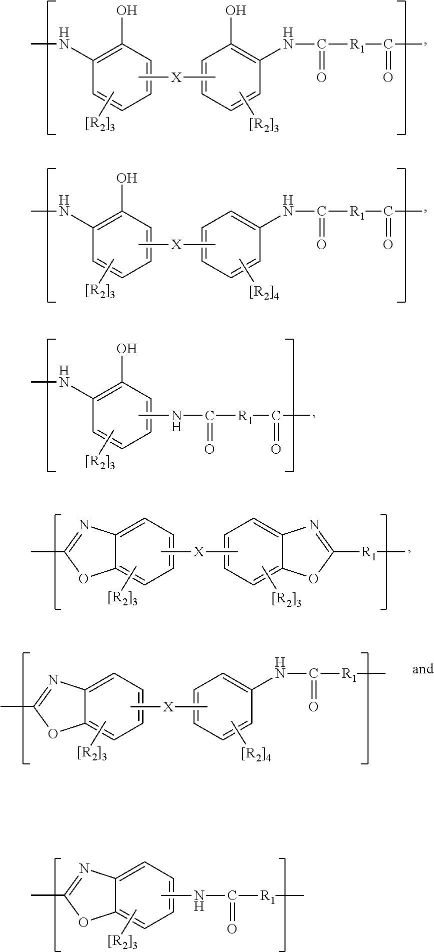

[R₁ represents a group having an aromatic ring or an alicyclic structure, and R₂ represents an arbitrary substituent group. The three or four R₂ groups may be identical or different. X represents a divalent atom or a divalent organic group.] The X atoms/groups are identical or different, and so are the R₁ groups.

### [Polymer Film]

The present disclosure, in another aspect, relates to a polymer film formed with the polymer solution according to the present disclosure (hereinafter also referred to as a “polymer film according to the present disclosure”).

The polymer film according to the present disclosure, at an equivalent thickness of 10 μm, in one or more embodiments, has a light transmittance at a wavelength of 400 nm of 60% or more, 65% or more, 70% or more, 75% or more, or 80% or more, for example, from the viewpoint of suitable use of the film in the production of a display element, an optical element, or an illumination element in one or more embodiments. Further, the polymer film according to the present disclosure, in one or more embodiments, has a fracture energy of 2.0 MJ/m³ or more, 2.5 MJ/m³ or more, 3.0 MJ/m³ or more, 3.5 MJ/m³ or more, or, 4.0 MJ/m³ or more, for example, from the viewpoint of improving handleability of the film in the production of a display element, an optical element, or an illumination element.

The polymer film according to the present disclosure, in one or more embodiments, has a benzoxazole structure. While a film is being formed or after a film is formed by using polymer solution according to the present disclosure having a benzoxazole precursor structure, a heat treatment (curing treatment) is applied, whereby the benzoxazole structure can be introduced into the film. The treatment temperature in the heat treatment is, in one or more embodiments, 200° C. or higher, 220° C. or higher, 240° C. or higher, 260° C. or higher, 280° C. or higher, 300° C. or higher, or, 320° C. or higher. Further, the treatment temperature in the heat treatment is, in one or more embodiments, 420° C. or lower, or, 400° C. or lower. The treatment temperature in the heat treatment is, in one or more embodiments, 5 to 300 minutes, or, 30 to 240 minutes.

### [Method for Producing Polymer Film]

The present disclosure, therefore, in another aspect, relates to a method for producing a polymer film, the method including a step a) of applying the polymer solution according to the present disclosure on a support material, and a step b) applying heat treatment to the polymer solution applied on the support after the step a), wherein the heat treatment is performed under the above-mentioned temperature and/or time conditions.

The present disclosure further relates to one or more embodiments described below.

<B1> A polymer film formed with the polymer solution according to any one of <A1> to <A10>.
<B2> The polymer film according to <B1>, wherein the polymer film, at an equivalent thickness of 10 μm, has a light transmittance at a wavelength of 400 nm of 60% or more.
<B3> The polymer film according to <B1> or <B2>, wherein heat treatment at 200° C. or higher is applied during or after film formation.
<B4> The polymer film according to any one of <B1> to <B3>, wherein the polymer film has a benzoxazole structure.
<B5> The polymer film according to any one of <B1> to <B4>, wherein the polymer film has a fracture energy of 2.0 MJ/m³ or more.

### [Stacked Composite]

In the present disclosure, a “stacked composite” refers to a composite obtained by laminating a glass plate and a polymer film layer. “Laminating a glass plate and a polymer film layer”, in one or more non-limited embodiments, refers to “laminating a glass plate and a polymer film layer directly”, and further, in one or more non-limited embodiments, refers to “laminating a glass plate and a polymer film layer with one or more layers being interposed therebetween”. In the present disclosure, the polymer film of the polymer film layer is the polymer film according to the present disclosure. The present disclosure, therefore, in one aspect, relates to a stacked composite that includes a glass plate and a polymer film layer, wherein the polymer film according to the present disclosure is stacked on one of surfaces of the glass plate; and in another aspect, the present disclosure relates to a stacked composite that includes a glass plate and a polymer film layer, wherein the polymer film according to the present disclosure is stacked on one of surfaces of the glass plate, the stacked composite being obtained or obtainable by applying the polymer solution according to the present disclosure over the glass plate (hereinafter, both of the same are also referred to as a “stacked composite according to the present disclosure”).

The stacked composite according to the present disclosure, in one or more non-limited embodiments, can be used in a method for producing a display element, an optical element, or an illumination element, an example of which is illustrated in FIG. 2; and further, in one or more non-limited embodiments, the stacked composite can be used as a stacked composite obtained in Step B of the producing method illustrated in FIG. 2. The stacked composite according to the present disclosure, therefore, in one or more non-limited embodiments, is a stacked composite to be used in a method for producing a display element, an optical element, or an illumination element, the method including the step of forming the display element, the optical element, or the illumination element on a surface of a polyamide resin layer, the surface being on a side opposite to a glass-plate-side surface thereof.

The stacked composite according to the present disclosure may further include an organic resin layer and/or an inorganic layer in addition to the polymer film layer. Examples of the additional organic resin layer, in one or more non-limited embodiments, includes a flattening coat layer. Further, examples of the inorganic layer, in one or more non-limited embodiments, include a gas barrier layer that suppresses permeation of water and oxygen, and a buffer coating layer that suppresses ion migration to TFT elements.

### [Polymer Film Layer]

The polymer film in the polymer film layer in the stacked composite according to the present disclosure is formed by using the polymer solution according to the present disclosure. The polymer film layer in the stacked composite according to the present disclosure has a thickness, in one or more embodiments, of 500 μm or less, 200 μm or less, or, 100 μm or less, for example, from the viewpoint of using the film in a display element, an optical element, or an illumination element, and from the viewpoint of suppressing occurrence of a crack in the polymer film layer. Further, the polymer film layer, in one or more non-limited embodiments, has a thickness of 1 μm or more, 2 μm or more, or, 3 μm or more, for example.

The polymer film layer in the stacked composite according to the present disclosure, at an equivalent thickness of 10 μm, in one or more embodiments, has a light transmittance at a wavelength of 400 nm of 60% or more, 65% or more, 70% or more, 75% or more, or 80% or more, for example, from the viewpoint that the film is suitably used in the production of a display element, an optical element, or an illumination element in one or more embodiments. Further, the polymer film layer in the stacked composite according to the present disclosure, in one or more embodiments, has a fracture energy of 2.0 MJ/m³ or more, 2.5 MJ/m³ or more, 3.0 MJ/m³ or more, 3.5 MJ/m³ or more, or 4.0 MJ/m³ or more, for example, from the viewpoint of improving handleability of the film in the production of a display element, an optical element, or an illumination element.

The polymer film layer in the stacked composite according to the present disclosure, in one or more embodiments, has a benzoxazole structure. A heat treatment (curing treatment) is applied while a polymer film layer is being formed or after the polymer film layer is formed using the polymer solution according to the present disclosure having a benzoxazole precursor structure, whereby the benzoxazole structure can be introduced to the film.

### [Glass Plate]

Examples of a material of the glass plate in the stacked composite according to the present disclosure, in one or more embodiments, include soda lime glass, and non-alkali glass, from the viewpoint of using the film in a display element, an optical element, or an illumination element. The glass plate in the stacked composite according to the present disclosure, in one or more embodiments, has a thickness of 0.3 mm or more, 0.4 mm or more, or, 0.5 mm or more, for example, from the viewpoint of using the film in a display element, an optical element, or, an illumination element. Further, the glass plate, in one or more embodiments, has a thickness of 3 mm or less, or, 1 mm or less, for example.

### [Method for Producing Stacked Composite]

The stacked composite according to the present disclosure can be produced by applying the polymer solution according to the present disclosure over a glass plate, drying the same, and applying a curing treatment (heat treatment) as required. By applying a curing treatment (heat treatment), the benzoxazole structure can be introduced to the film. The treatment temperature of the heat treatment, in one or more embodiments, is 200° C. or higher, 220° C. or higher, 240° C. or higher, 260° C. or higher, 280° C. or higher, 300° C. or higher, or, 320° C. or higher. Further, the treatment temperature of the heat treatment, in one or more embodiments, is 420° C. or lower, or 400° C. or lower. The treatment temperature of the heat treatment, in one or more embodiments, is 5 to 300 minutes, or, 30 to 240 minutes.

The present disclosure further relates to one or more embodiments described below.

<C1> A stacked composite including a glass plate and a polymer film layer, wherein a polymer film is stacked on one of surfaces of the glass plate, wherein the stacked composite is obtained by applying the polymer solution according to any one of <A1> to <A10> over the glass plate.
<C2> The stacked composite according to <C1>, wherein the glass plate has a thickness of 0.3 mm or more.
<C3> The stacked composite according to <C1> or <C2>, wherein the polymer film has a thickness of 500 μm or less.
<C4> The stacked composite according to any one of <C1> to <C3>, wherein the polymer film, at an equivalent thickness 10 μm, has a light transmittance at a wavelength of 400 nm of 60% or more.
<C5> The stacked composite according to any one of <C1> to <C4>, wherein the polymer film has a benzoxazole structure.
<C6> The stacked composite according to any one of <C1> to <C5>, wherein the polymer film has a fracture energy of 2.0 MJ/m³ or more.

### [Display Element, Optical Element, or Illumination Element]

In the present disclosure, “a display element, an optical element, or an illumination element” refers to an element that composes a display body (display device), an optical device, or an illumination device, examples of which include an organic electroluminescent (EL) element, a liquid crystal element, and an organic EL lighting. Further, examples of the same include an element that composes a part of the above-mentioned devices, such as a thin film transistor (TFT) element, and a color filter element. Examples of the display element, the optical element, or the illumination element according to the present disclosure, in one or more embodiments, include those which are produced using the polymer solution according to the present disclosure, and those in which the polymer film according to the present disclosure is used as a substrate for a display element, an optical element, or an illumination element.

### <One Non-Limited Embodiment of Organic EL Element>

An embodiment of an organic EL element, which is an embodiment of the display element according to the present disclosure is described below, with reference to the drawings.

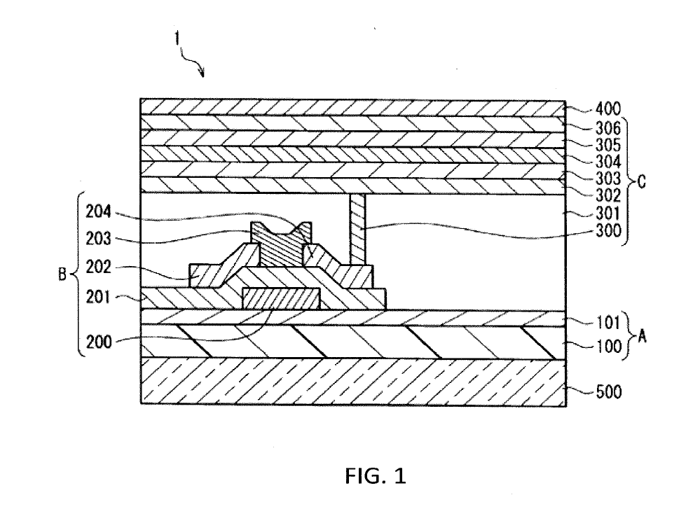

FIG. 1 is a schematic cross-sectional view illustrating an organic EL element 1 according to one embodiment. The organic EL element 1 includes a thin film transistor B and an organic EL layer C formed on a substrate A. The entirety of the organic EL element 1 is covered with a sealing layer 400. The organic EL element 1 may be an element separated from a support material 500, or may include the support material 500. The following description describes each configuration in detail.

### 1. Substrate A

The substrate A includes a transparent resin substrate 100, and a gas barrier layer 101 formed on a top surface of the transparent resin substrate 100. Here, the transparent resin substrate 100 is the polymer film according to the present disclosure.

The transparent resin substrate 100 may be annealed with heat. This is effective in eliminating distortion of the substrate, reinforcing the stability of dimensions against environmental changes, and the like.

The gas barrier layer 101 is a thin film made of SiOx, SiNx, or the like, and is formed by a vacuum film forming method such as the sputtering method, the CVD method, or the vacuum vapor deposition method. The gas barrier layer 101 has a thickness of about 10 nm to 100 nm typically, but the thickness is not limited to this. Here, the gas barrier layer 101 may be formed on a surface opposite to the surface where the gas barrier layer 101 is formed in FIG. 1, or may be formed on both of the surfaces.

### 2. Thin Film Transistor

The thin film transistor B includes a gate electrode 200, a gate insulating film 201, a source electrode 202, an active layer 203, and a drain electrode 204. The thin film transistor B is formed on the gas barrier layer 101.

The gate electrode 200, the source electrode 202, and the drain electrode 204 are transparent thin films made of indium tin oxide (ITO), indium zinc oxide (IZO), zinc oxide (ZnO), or the like. The method for forming the transparent thin film is, for example, the sputtering method, the vacuum vapor deposition method, or the ion plating method. These electrodes have a film thickness of about 50 nm to 200 nm, typically, but the thickness of the same is not limited to this.

The gate insulating film 201 is a transparent insulation thin film made of SiO₂, Al₂O₃, or the like, by the sputtering method, the CVD method, the vacuum vapor deposition method, the ion plating method, or the like. The gate oxide film has a film thickness of about 10 nm to 1 μm, typically, but the thickness of the same is not limited to this.

The active layer 203 is made of monocrystalline silicon, low-temperature polysilicon, amorphous silicon, oxide semiconductor, or the like, among which an optimal one is used appropriately. The active layer is formed by the sputtering method or the like.

### 3. Organic EL Layer

An organic EL layer C includes a conductive connection part 300, a flattening layer 301 that is insulative, a lower electrode 302 that is an anode of the organic EL element 1, a hole transport layer 303, a light emission layer 304, an electron transport layer 305, and an upper electrode 306 that is a cathode of the organic EL element 1. The organic EL layer C is formed at least above the gas barrier layer 101 or the thin film transistor B, and the lower electrode 302 and the drain electrode 204 of the thin film transistor B are electrically connected with each other via the connection part 300. In place of this configuration, the lower electrode 302 of the thin film transistor B and the source electrode 202 may be connected with each other via the connection part 300.

The lower electrode 302 is an anode of the organic EL element 1, and is a transparent thin film made of indium tin oxide (ITO), indium zinc oxide (IZO), zinc oxide (ZnO), or the like. It should be noted that ITO is preferable, with which high transparency, high conductivity, and the like can be achieved.

To form the hole transport layer 303, the light emission layer 304, and the electron transport layer 305, a conventionally known material for an organic EL element can be used without any change.

The upper electrode 306 is formed with, for example, films made of lithium fluoride (LiF) and aluminum (Al) in such a manner that the films have thicknesses of 5 nm to 20 nm, and 50 nm to 200 nm, respectively. The method for forming the films is, for example, the vacuum vapor deposition method.

Further, in a case where an organic EL element of a bottom emission-type is to be produced, the upper electrode 306 in the upper part of the organic EL element 1 may be an electrode of a light reflection type. With this, light that is generated in the organic EL element 1 and travels upward on a side opposite to the display side is reflected by the upper electrode 306. As a result, the reflected light is also used for display, which improves the utilization efficiency of light emitted by the organic EL element.

### [Method for Producing Display Element, Optical Element, or Illumination Element]

The present disclosure, in another aspect, relates to a method for producing a display element, an optical element, or an illumination element. The producing method according to the present disclosure, in one or more embodiments, is a method for producing a display element, an optical element, or an illumination element according to the present disclosure. Further, the producing method according to the present disclosure, in one or more embodiments, is a producing method including the steps of: applying the polymer solution according to the present disclosure to a support material; forming a polymer film after the applying step; and forming a display element, an optical element, or an illumination element on a surface of the polymer film that is not in contact with the support material. The producing method according to the present disclosure may further include the step of separating the display element, the optical element, or the illumination element formed on the support material, from the support material.

### <One Non-Limited Embodiment of Method for Producing Organic EL Element>

The following description describes one embodiment of a method for producing an organic EL element, as one embodiment of the method for producing the display element according to the present disclosure, while referring to the drawings.

A method for producing the organic EL element 1 illustrated in FIG. 1 includes a fixing step, a gas barrier layer forming step, a thin film transistor forming step, an organic EL layer forming step, a sealing step, and a separating step. Hereinafter, each step is described in detail.

### 1. Fixing Step

In the fixing step, the transparent resin substrate 100 is fixed on the support material 500. The method for fixing is not limited particularly, and examples of the same include a method of applying an adhesive between the support material 500 and the transparent resin substrate 100, and a method of fusing a part of the transparent resin substrate 100 onto the support material 500. As the material for the support material 500, for example, glass, a metal, silicon, a resin, or the like can be used. These may be used alone, or two or more of the materials may be used in combination appropriately. Further alternatively, the fixing may be achieved by applying a mold release agent or the like on the support material 500, and attaching the transparent resin substrate 100 on the same. In one or more embodiments, the polymer solution according to the present disclosure is applied on the support material 500, and is dried, whereby the polymer film (transparent resin substrate) 100 is formed.

### 2. Gas Barrier Layer Forming Step

In the gas barrier layer forming step, the gas barrier layer 101 is formed on the transparent resin substrate 100. The forming method is not limited particularly, and any known method can be used.

### 3. Thin Film Transistor Forming Step

In the thin film transistor forming step, the thin film transistor B is formed on the gas barrier layer 101. The forming method is not limited particularly, and any known method can be used.

### 4. Organic EL Layer Forming Step

The organic EL layer forming step includes a first step and a second step. In the first step, the flattening layer 301 is formed. The method for producing the flattening layer 301 is, for example, a method of applying a photosensitive transparent resin by the spin coating method, the slit coating method, the ink-jet method, or the like. Here, it is necessary to provide an opening in the flattening layer 301, so that the connection part 300 can be formed in the second step. The flatten layer has a film thickness of about 100 nm to 2 μm, typically, but the thickness is not limited to this.

In the second step, first of all, the connection part 300 and the lower electrode 302 are formed simultaneously. Examples of the method for forming these include the sputtering method, the vacuum vapor deposition method, and the ion plating method. The electrode has a film thickness of about 50 nm to 200 nm, typically, but the thickness is not limited to this. Thereafter, the hole transport layer 303, the light emission layer 304, the electron transport layer 305, and the upper electrode 306, which is a cathode of the organic EL element 1, are formed. As a method for forming these, a method suitable for the used materials and the laminate configuration can be used, such as the vacuum vapor deposition method or the application method. Further, the configuration of the organic layers of the organic EL element 1 may additionally include other known organic layers selected appropriately, such as a positive hole injection layer, an electron transport layer, a positive hole blocking layer, and an electron blocking layer, irrespective of the description of the present example.

### 5. Sealing Step

In the sealing step, the organic EL layer A is sealed from above the upper electrode 306, by the sealing layer 400. The sealing layer 400 can be made of glass, a resin, ceramic, a metal, a metal compound, or a composite of any of these, for example, and an optimal material can be appropriately selected.

### 6. Separating Step

In the separating step, the formed organic EL element 1 is separated from the support material 500. A method for realizing the separating step is, for example, a method of separating the same from the support material 500 physically. Here, the configuration may be such that a separation layer is provided on the support material 500, or the separation may be achieved by inserting a wire between the support material 500 and the display element. Further, other examples of the separating method include the following methods: a method in which a separation layer is not provided on an end of the support material 500, and the element is taken out by cutting the inside from the end after the element is formed; a method in which a layer composed of a silicon layer and the like is provided between the support material 500 and the element, and the element is separated by laser irradiation; a method in which heat is applied to the support material 500 so as to separate the support material 500 and the transparent substrate; and a method in which the support material 500 is removed with a solvent. Each of these methods may be used alone or more arbitrary methods among these may be used in combination.

The organic EL element obtained by the method for producing a display element, an optical element, or an illumination element according to the present embodiment, in one or more embodiments, has excellent transparency, excellent heat-resisting properties, low linear expansion properties, low optical anisotropy, and the like.

### [Display Device, Optical Device, Illumination Device]

The present disclosure, in aspects thereof, relates to a display device, an optical device, or an illumination device in which the display element, the optical element, or the illumination element according to the present disclosure is used, and further, relates to a method for producing the same. Examples of the display device include an image pickup element, though not limited to this, examples of the optical device include an optical/electric composite circuit, though not limited to this, and examples of the illumination device include a TFT-LCD, and an OEL illumination, though not limited to these.

The present invention further relates to one or more embodiments described below.

<D1> A method for producing a display element, an optical element, or an illumination element, the method including the step of forming a display element, an optical element, or an illumination element on a surface of the polymer layer of the stacked composite according to any one of <C1> to <C6>, the surface being on a side opposite to a glass-plate-side surface thereof.
<D2> The method for producing a display element, an optical element, or an illumination element according to <D1>, further including the step of separating the display element, the optical element, or the illumination element thus formed, from the glass plate.
<D3> A display element, an optical element, or an illumination element produced using the polymer solution according to any one of <A1> to <A10>, or using the polymer film according to any one of <B1> to <B5>, the display element, the optical element, or the illumination element including the polymer film.

### EXAMPLE

The present invention is described hereinafter with reference to an example and a comparative example, though the present invention is not limited to the example described below.

First of all, the method for measuring film properties in the present example is described.

### [Fracture Energy]

A tensile test was carried out using a universal tensile tester (Autograph AG-5kNX, produced by Shimadzu Corporation), and fracture energy was calculated from the measurement result.

Measurement conditions are as follows:
Sample size: width: 5 mm, length: 55 mm, thickness: 0.01 mm (rectangular shape)
Tensile speed: 5 mm/min
Gripper distance: 25 mm

### [Transmittance]

Using a spectrophotometer (V-670, produced by JASCO Corporation), light transmittance at each wavelength was measured. As the values in the present example, values obtained in the total light transmittance mode were used. In Table 1 shown below, light transmittances at a wavelength of 400 nm when the film thickness was converted to 10 μm are shown.

### Example 1

In a 500-mL four-mouth separable flask equipped with a thermometer, an agitator, and a nitrogen introducing pipe, 2,2′-ditrifluoromethyl-4,4′-diamino-biphenyl (PFMB: produced by SEIKA Corporation, 20.00 g), and 3,3′-diamino-4,4′-hydroxy-biphenyl (DADHBP: 1.50 g) were dissolved in dimethylacetamide (produced by Kanto Chemical Co. Inc., 257.60 g). To this solution, propylene oxide (produced by Wako Pure Chemical Industries, Ltd., 12.09 g) was added, and was cooled to 0° C. in a nitrogen atmosphere. Then, isophthaloyl chloride (produced by Tokyo Chemical Industry Co., Ltd., 12.67 g), and terephthaloyl chloride (TPC: produced by Tokyo Chemical Industry Co., Ltd., 1.41 g) were added thereto, and agitated 4 hours. Thereafter, benzoyl chloride (produced by Tokyo Chemical Industry Co., Ltd., 0.02 g) was added, and was further agitated for one hour. The reaction solution thus obtained was added to a large excess of methanol, and deposited precipitate was collected by filtering. The precipitate was washed with methanol, and was dried sufficiently, whereby a polymer was obtained. The obtained polymer was dissolved in 300 g of a mixture solvent of butyl cellosolve and N,N-dimethylacetamide which were at a ratio of 15:85 by weight. The polymer solution was applied using a spin coater, and heat treatment at 330° C. was applied thereto in an oven for 60 minutes, whereby a film was formed. Properties (fracture energy, light transmittance) of the obtained film were evaluated.

The obtained film had a light transmittance at a wavelength of 400 nm of 84.1%, and a fracture energy of 13.8 MJ/m³.

### Comparative Example 1

A polymer solution and a polymer film were formed in the same manner as that of Example 1 except that 2,2′-ditrifluoromethyl-4,4′-diamino-biphenyl was used alone as diamine, and properties of the obtained film were evaluated.

The obtained film had a light transmittance at a wavelength of 400 nm of 82.2%, and a fracture energy of 7.48 MJ/m³.

Results of Example 1 and Comparative Example 1 are compiled in the table shown below.

TABLE 1

| | | | | | | Evaluation of properties | |
|---|---|---|---|---|---|---|---|
| | Composition (mol %) | | | | Temp. of | Light transmittance | Fracture |
| | Diamine | | Diacid dichloride | | film heat | at 400 nm | energy |
| | PFMB | DADHBP | TPC | IPC | treatment | % | MJ/m³ |
| Ex. 1 | 90 | 10 | 10 | 90 | 330° C. | 84.1 | 13.8 |
| Comp. Ex. 1 | 100 | — | 10 | 90 | 330° C. | 82.2 | 7.48 |

As is clear from Table 1, the polymer solution of the polymer in which DADHBP was used (Example 1) enables the production of a polymer film with improved light transmittance and improved transparency, as compared with Comparative Example 1. Further, it is also clear that the polymer solution of the polymer in which DADHBP was used (Example 1) enables the production of a polymer film with improved fracture energy and improved tenacity of the film, as compared with Comparative Example 1.

[Description of Reference Numerals]

| | |
|---|---|
| 1 | Organic electroluminescent (EL) element |
| 100 | Transparent resin substrate |
| 101 | Gas barrier film |
| 200 | Gate electrode |
| 201 | Gate insulating film |
| 202 | Source electrode |
| 203 | Active layer |
| 204 | Drain electrode |
| 300 | Conductive connection part |
| 301 | Flattening layer |
| 302 | Lower electrode |
| 303 | Hole transport layer |
| 304 | Light emission layer |
| 305 | Electron transport layer |
| 306 | Upper electrode |
| 400 | Sealing layer |
| 500 | Support material |
| A | Substrate |
| B | Thin film transistor |
| C | Organic EL layer |

1. A polymer solution, comprising:
a solvent; and
a polymer that comprises either a structural unit having a benzoxazole precursor structure or a structural unit having a benzoxazole structure.

2. The polymer solution according to claim 1,
wherein a sum of the structural unit having a benzoxazole precursor structure and the structural unit having a benzoxazole structure with respect to all of the structural units composing the polymer is more than 0 mol % and equal to or less than 50 mol %.

3. The polymer solution according to claim 1, wherein the structural unit having a benzoxazole precursor structure or the structural unit having a benzoxazole structure is at least one selected from the group consisting of structural units expressed by chemical formulae: 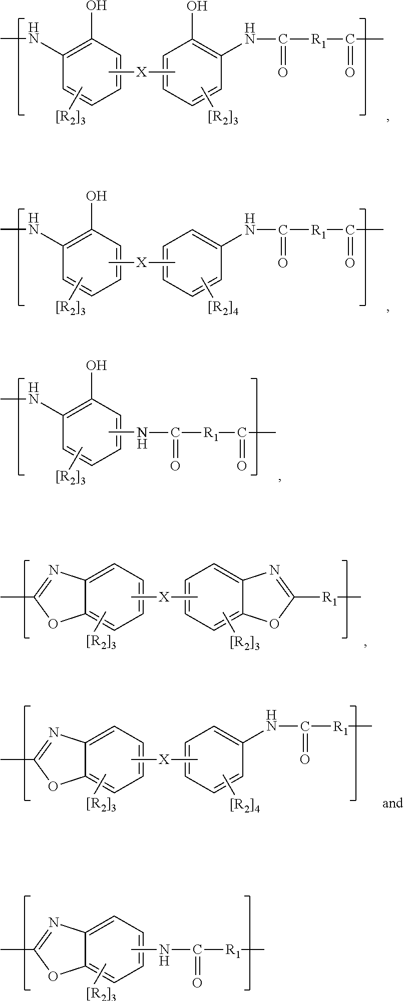
where R₁ represents a group having an aromatic ring or an alicyclic structure, R₂ represents an arbitrary substituent group, the three or four R₂ groups are identical or different, and X represents a divalent atom or a divalent organic group.

4. The polymer solution according to claim 1,
wherein an amount of a diamine component monomer having a benzoxazole precursor structure with respect to a total amount of diamine component monomers used in synthesis of the polymer is more than 0 mol % and equal to or less than 50 mol %.

5. The polymer solution according to claim 4,
wherein the diamine component monomer having a benzoxazole precursor structure used in the synthesis of the polymer is at least one selected from the group consisting of monomers expressed by chemical formulae: 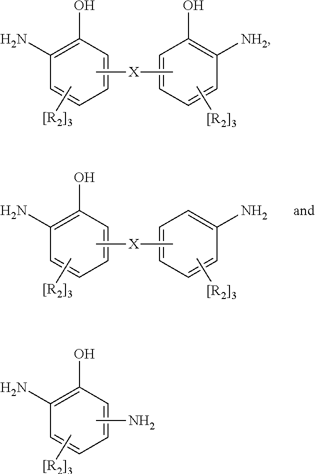
where R₂ represents an arbitrary substituent group, the three or four R₂ groups are identical or different, and X represents a divalent atom or a divalent organic group.

6. The polymer solution according to claim 1, wherein a film formed with the polymer solution, at an equivalent thickness of 10 μm, has a light transmittance at a wavelength of 400 nm of 60% or more.

7. The polymer solution according to claim 6, wherein the film formed with the polymer solution has a fracture energy of 2.0 MJ/m³ or more.

8. The polymer solution according to claim 1, wherein the polymer comprises a structural unit expressed by Chemical Formula (I), (II), (III), (IV), (V) or (VI) and a structural unit expressed by Chemical Formula (VII), (VIII), (IX), or (X), and
expressions (1) and (2) are satisfied
0<l+m+n+o+p+q≦50 (1)
50≦r+s+t+u<100 (2)
where each of l, m, n, o, p, q, r, s, t, and u indicates a mole fraction of the structural units expressed by Chemical Formula (I), (II), (III), (IV), (V), (VI), (VII), (VIII), (IX), and (X) in the polymer, 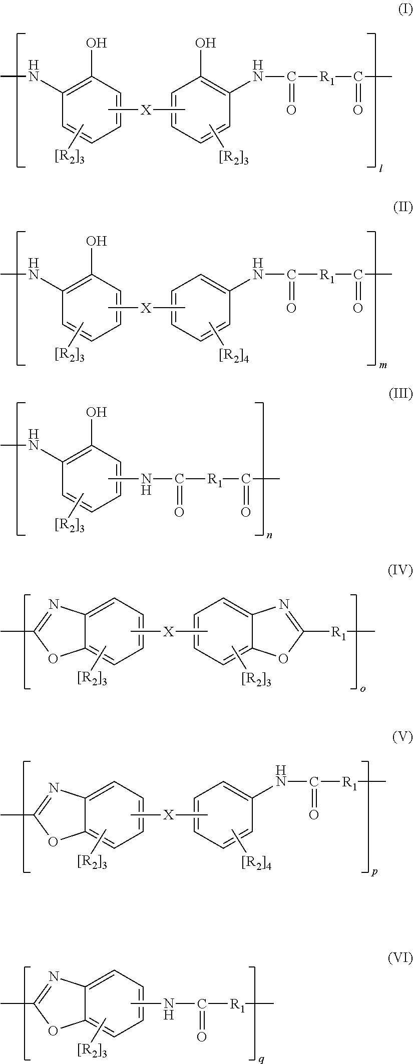
where R₁ represents a group having an aromatic ring or an alicyclic structure, R₂ represents an arbitrary substituent group, the three or four R₂ groups may be identical or different, and X represents a divalent atom or a divalent organic group, 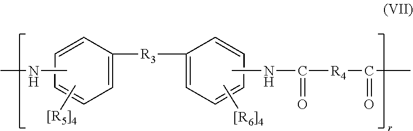
where R₃ represents a group having an aromatic ring or an alicyclic structure, R₄ represents a group having an aromatic ring or an alicyclic structure, R₅ represents an arbitrary substituent group, R₆ represents an arbitrary substituent group, the four R₅ groups are identical or different, the four R₆ groups are identical or different, and the structural units expressed by Formula (VII) do not include the structural units expressed by Formulae (I) and (II), 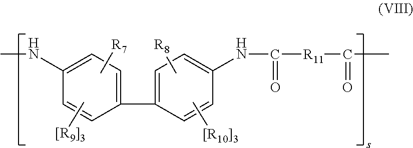
where R₇ represents an electron-withdrawing group, R₈ represents an electron-withdrawing group, R₉ represents an arbitrary substituent group, R₁₀ represents an arbitrary substituent group, R₁₁ represents a group having an aromatic ring or an alicyclic structure, the three R₉ groups are identical or different, the three R₁₀ groups are identical or different, and the structural units expressed by Formula (VIII) do not include the structural units expressed by Formulae (I) and (II), 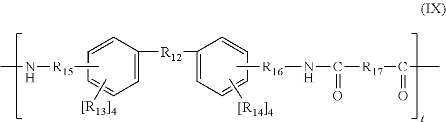
where R₁₂ represents a group containing Si, a group containing P, a group containing S, a halogenated hydrocarbon group, or a group containing an ether bond, the R₁₂ groups are identical or different, R₁₃ represents an arbitrary substituent group, R₁₄ represents an arbitrary substituent group, R₁₅ represents a directly bonded phenyl group or an arbitrary group having 6 to 12 carbon atoms and containing a phenyl group, R₁₆ represents a directly bonded phenyl group or an arbitrary group having 6 to 12 carbon atoms and containing a phenyl group, R₁₇ represents a group having an aromatic ring or an alicyclic structure, the four R₁₃ groups are identical or different, the four R₁₄ groups are identical or different, and the structural units expressed by Formula (IX) do not include the structural units expressed by Formulae (I) and (II), and 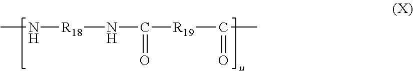
where R₁₈ represents a group having an aromatic ring or an alicyclic structure, R₁₉ represents a group having an aromatic ring or an alicyclic structure, the structural units expressed by Formula (X) do not include the structural unit expressed by Formula (III).

9. The polymer solution according to claim 1, wherein at least one end of the polymer is end-capped.

10. The polymer solution according to claim 1, wherein the polymer comprises a plurality of units of at least one selected from the group consisting of structural units expressed by chemical formulae: 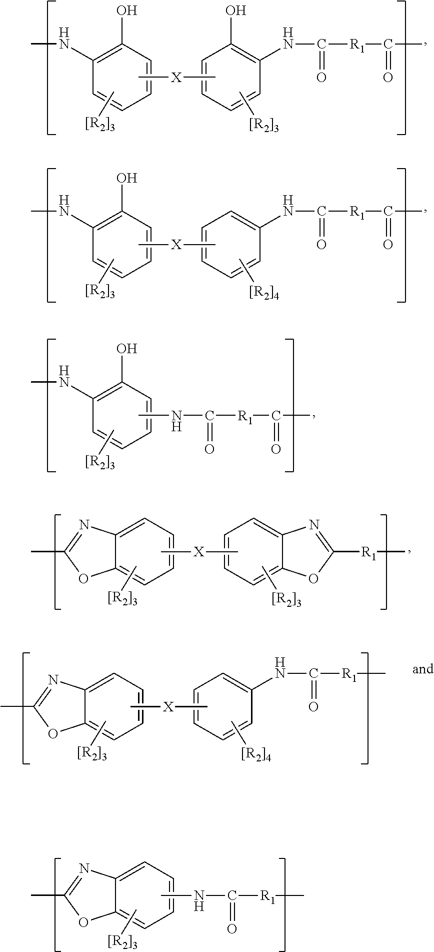
where R₁ represents a group having an aromatic ring or an alicyclic structure, R₂ represents an arbitrary substituent group, the three or four R₂ groups are identical or different, X represents a divalent atom or a divalent organic group, the X atoms or groups are identical or different, and the R₁ groups are identical or different.

11. A polymer film formed with the polymer solution according to claim 1.

12. The polymer film according to claim 11, wherein the polymer film, at an equivalent thickness of 10 μm, has a light transmittance at a wavelength of 400 nm of 60% or more.

13. The polymer film according to claim 11, wherein heat treatment at 200° C. or higher is applied during or after the film is formed.

14. The polymer film according to claim 11, wherein the polymer film has a benzoxazole structure.

15. The polymer film according to claim 11, wherein the polymer film has a fracture energy of 2.0 MJ/m³ or more.

16. A stacked composite, comprising:
a glass plate; and
a polymer film layer,
wherein the polymer film layer is stacked on one of surfaces of the glass plate, and the stacked composite is obtained by a process comprising applying the polymer solution according to claim 1 over the glass plate.

17. The stacked composite according to claim 16, wherein the glass plate has a thickness of 0.3 mm or more.

18. The stacked composite according to claim 16, wherein the polymer film layer has a thickness of 500 μm or less.

19. The stacked composite according to claim 16, wherein the polymer film layer, at an equivalent thickness 10 μm, has a light transmittance at a wavelength of 400 nm of 60% or more.

20. The stacked composite according to claim 16, wherein the polymer film layer has a benzoxazole structure.

21. The stacked composite according to claim 16, wherein the polymer film layer has a fracture energy of 2.0 MJ/m³ or more.

22. A method for producing a display element, an optical element, or an illumination element, the method comprising:
forming a display element, an optical element, or an illumination element on a surface of the polymer film layer of the stacked composite according to claim 16, the surface being on a side opposite to the surface on which the glass plate is stacked.

23. The method according to claim 22, further comprising:
separating the display element, the optical element, or the illumination element from the glass plate.

24. A display element, an optical element, or an illumination element comprising a polymer film produced by a process comprising curing the polymer solution according to claim 1.
